(19) United States
(12) Patent Application Publication
(10) Pub. No.: US 2014/0070277 A1
(43) Pub. Date: Mar. 13, 2014

(54) EPITAXIAL GROWTH OF SMOOTH AND HIGHLY STRAINED GERMANIUM

(71) Applicant: International Business Machines Corporation, Armonk, NY (US)

(72) Inventors: Thomas N. Adam, Slingerlands, NY (US); Stephen W. Bedell, Wappingers Falls, NY (US); Keith E. Fogel, Hopewell Junction, NY (US); Alexander Reznicek, Troy, NY (US); Devandra Sadana, Pleasantville, NY (US)

(21) Appl. No.: 14/081,032

(22) Filed: Nov. 15, 2013

Related U.S. Application Data
(62) Division of application No. 13/526,840, filed on Jun. 19, 2012.

(51) Int. Cl. H01L 29/165; H01L 29/78

(52) U.S. Cl. CPC H01L 29/165; H01L 29/7848; H01L 29/7842
USPC 257/192

(57) ABSTRACT

A smooth germanium layer which can be grown directly on a silicon semiconductor substrate by exposing the substrate to germanium precursor in the presence of phosphine at temperature of about 350 C. The germanium layer formation can be achieved with or without a SiGe seed layer. The process to form the germanium layer can be integrated into standard CMOS processing to efficiently form a structure embodying a thin, highly strained germanium layer. Such structure can enable processing flexibility. The germanium layer can also provide unique physical properties such as in an opto-electronic devices, or to enable formation of a layer of group III-V material on a silicon substrate.

### CROSS-REFERENCE TO RELATED APPLICATIONS

This application is a divisional of and claims priority from U.S. application Ser. No. 13/526,840 filed on Jun. 19, 2012, the entire contents of which are incorporated by reference herein.

### BACKGROUND

The present invention relates to semiconductor integrated circuits and, more particularly, relates to forming a smooth germanium layer on a silicon substrate.

A germanium film on a silicon substrate can have a number of advantageous characteristics for semiconductor processing. For example, germanium has a different band gap than silicon and can absorb wavelengths that are not absorbed by silicon. More specifically, germanium can absorb 1.55 um (micrometer) wavelength light (which can be used for optical communications), and can generate electron-hole pairs from that light. As such, germanium grown directly on silicon is desirable for a variety of optoelectronic applications, such as utilizing germanium as a detector material.

Germanium can also enable formation of a layer of group III-V material on a silicon substrate, which can be referred to as ‘monolithic III-V integration’. Group III-V materials (i.e., including at least one of a group III element such as Al, Ga, or In and at least one of a group V element such as N, P, As, or Sb) such as GaAs or InP generally are direct band gap semiconductors and furthermore have a much higher hole and electron mobility relative to silicon. Group III-V materials have promise as high-mobility channels of the future, and as optoelectronic detectors and sources. These materials can be grown on epitaxial germanium, but cannot easily be grown directly on epitaxial silicon.

Additionally, germanium can be easily and highly selectively etched relative to silicon. Thus germanium could be used to form sacrificial structures within a semiconductor manufacturing flow.

However, growing a germanium film on silicon can be problematic. Often a very rough surface can result, or such growth is prohibitively slow or requires impractical or unattainable reactor and precursor purity. For example, a recent patent to Carothers et al (US 2011/0036289 A1) teaches that a smooth bulk germanium layer can be grown after forming an “intrinsic germanium seed layer”, and then a p- or n- doped germanium seed layer. Carothers teaches to form the ‘intrinsic layer’ by exposing a preconditioned substrate to germane gas for 2 hours at 350 C, and then form the ‘doped layer’ after heating slowly to 600 C, by adding dopant to the germane chamber. Carothers suggests that some dopant diffuses into the intrinsic layer and reduces stress imposed by the lattice mismatch between Ge and Si crystal, and that enables growth of a smooth doped or undoped bulk germanium layer.

As market demands continue to seek increased capabilities on ever smaller and more compact integrated circuits, there continues to be a need for less expensive or complicated methods to form epitaxial germanium on silicon.

### BRIEF SUMMARY

According to a first embodiment, the invention provides a method to grow a germanium film on a silicon substrate by exposing the silicon substrate to germanium precursor and phosphine while maintaining temperature at or below 370 C. The method can be conducted in an RPCVD chamber. The process pressure can be in the range of 10 to 400 torr and the phosphine partial pressure can be in the range of 1e−5 to 1e−2 torr. A surface of the silicon substrate can be crystalline Si or crystalline SiGe, which SiGe can be formed prior to the germanium growth step and can be in-situ doped. The growth can continue to form a thick layer of germanium, or in just a few minutes can form a germanium film with thickness in the range of 0.5 nm to 10 nm. The method can include forming a cap of silicon or SiGe over the germanium layer. In embodiments, the germanium film can include more than 1.3% strain.

According to another embodiment, the invention provides a structure comprising a germanium layer having strain greater than 1.5% and disposed on a silicon layer. The germanium layer can be disposed directly on the silicon layer. The silicon layer can have chemical formula SiₓGe₁₋ₓ, where x can be 1, or in other embodiments x is in the range of 0.3 to 0.7. The silicon layer can be doped and the structure can include a silicon or SiGe cap formed over said germanium layer.

According to yet another embodiment, the invention provides a semiconductor article including a germanium layer disposed on a semiconductor substrate, wherein said germanium includes strain greater than 1.5%. The article can include a field effect transistor (FET), where the germanium layer is formed in the source/drain region of the FET. In certain embodiments, the germanium layer can have strain in the range of 1.5 to 2.8%.

### BRIEF DESCRIPTION OF SEVERAL VIEWS OF THE DRAWINGS

Exemplary embodiments may best be understood by reference to the detailed description in conjunction with the accompanying figures. The Figures are for provided for illustration and are not necessarily drawn to scale.

FIG. 1A illustrates a smooth epitaxial germanium layer formed on a silicon substrate according to a method of the present invention.

FIG. 1B depicts a plan view of substrate 10 showing multiple regions of crystalline SiGe rather than a continuous layer.

FIGS. 2-4 illustrate a CMOS structure that includes a strained region formed according to an embodiment of the present invention.

### DETAILED DESCRIPTION

The present disclosure relates to forming epitaxial germanium on silicon and related structures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

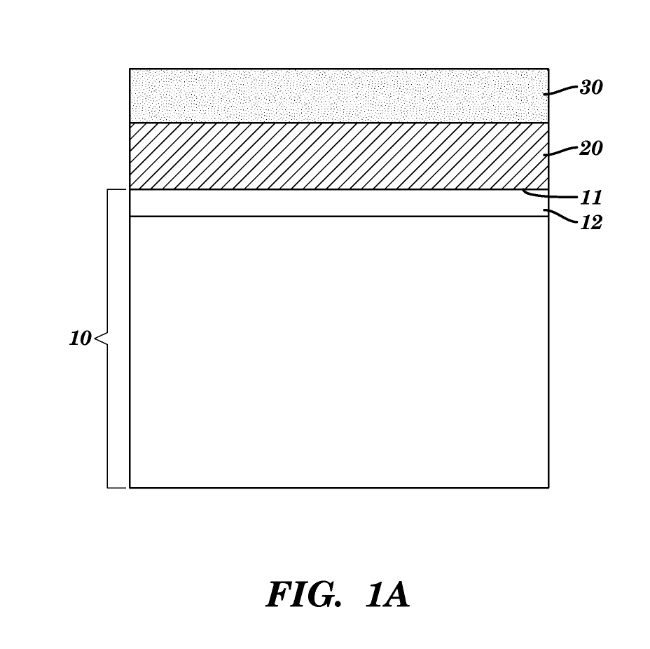

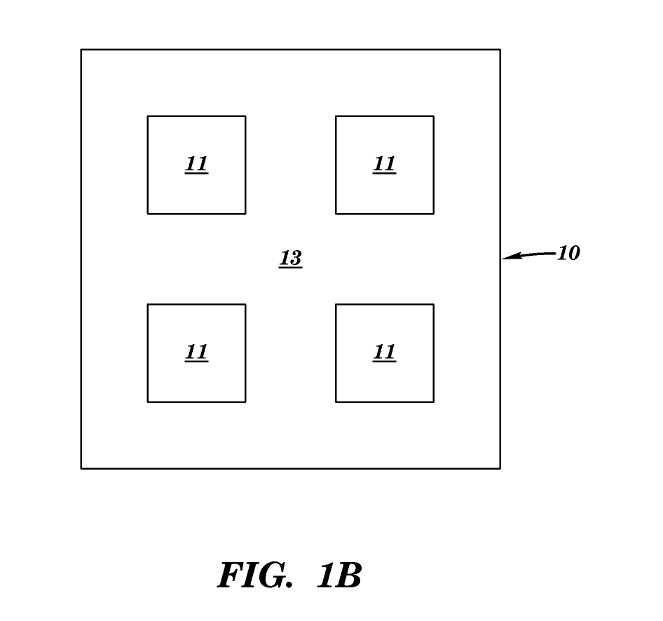

Referring now to FIG. 1, there is illustrated a substrate 10. Substrate 10 includes a semiconductor material having a significant silicon content. The semiconductor material of substrate 10 may be referred to herein as the ‘silicon layer’. The semiconductor material of substrate 10 can be bulk silicon or a compound of silicon such as Si:C (carbon doped silicon, with Carbon 0.2-4%) or SiGe (with any Ge content up to about 80% or 90%). The semiconductor material of substrate 10 can include dopants to increase electron or hole mobility as is known. Substrate 10 can comprise layers such as, silicon/silicon germanium, silicon on insulator (SOI), ETSOI (extremely thin semiconductor on insulator), PDSOI (partially-depleted semiconductor on insulator) or silicon germanium-on-insulator. The insulator layers of these can be referred to as a buried oxide (BOX) layer which can be any insulating oxide such as, e.g., silicon dioxide, or even an epitaxial oxide such as Gadolinium(III)-oxide (Gd₂O₃). Further, substrate 10 can be semiconductor wafer, or any part thereof, such as an integrated circuit chip singulated from such a wafer. One or more semiconductor devices (not shown) can be formed in or on substrate 10.

The top region 12, and therefore the top surface 11 of substrate 10 can have the same composition as the semiconductor material of substrate 10 (i.e., Si, Si:C, or SiGe). It can be advantageous if top region 12 and surface 11 constitutes SiGe. The SiGe of region 12 can have any Ge content, and in certain embodiments the Ge content can be in the range of 40% to 70%. Region 12 can be un-doped or lightly n-doped, such as with phosphorous.

Optionally, a thin SiGe layer can be grown as a top layer (region 12) of substrate 10 according to known techniques using SiGe precursors such as silane (SiH₄) and germane (GeH₄). The thin SiGe may extend substantially over substrate 10 (as a continuous layer) or can be one or more localized region(s) of crystalline SiGe as depicted in FIG. 1B. As a further option, the SiGe layer or region can be grown in the presence of dopant such as (but not limited to) phosphine or diborane such that region 12 is doped SiGe. If the semiconductor material of substrate 10 is not SiGe, layer 12 can be a thin buffer layer, such as having a thickness in the range of 1 to 10 nm. The top surface 11 of substrate 10, with or without a separate SiGe layer 12, constitutes a seed layer for subsequent growth of germanium layer 20.

The entirety of surface 11 can be crystalline and can be a monocrystalline surface substantially free of grain boundaries or dislocations, but the invention is not so limited. Surface 11 can be polycrystalline (comprising a number of crystal ‘grains’), and can be a continuous layer or may be one or more isolated crystalline regions 11 within field 13, where the material of field 13 need not be crystalline.

Substrate 10, including surface 11, can be preconditioned (i.e., cleaned) under hydrogen at between 600 and 1100 C, for example at about 1050 C. Alternatively, substrate 10 can be prepared by plasma assisted dry clean which process is described by US Application 2010/0255661.

As noted, the semiconductor material of substrate 10 has significant silicon content so surface 11 can be a SiGe surface, or surface 11 can be Si or Si:C. Referring again to FIG. 1, a germanium layer 20 can be formed on surface 11 by exposing surface 11 to a germanium precursor 22 in the presence of a proper concentration of phosphine. The germanium layer 20 can be formed by chemical vapor deposition (CVD) at temperature at or below 370 C, such as at about 350 C or in the range of 320-370 C. Growth of layer 20 can occur over a wide pressure range, such as in an ultra high vacuum CVD chamber at process pressures on the order of 1e−4 torr, or at significantly higher process pressures such as 100 torr or even 400 torr. In embodiments, a germanium layer can be grown in a reduced pressure CVD chamber (RPCVD) at a process pressure in the range of 10-30 torr. Germanium precursor 22 can be any appropriate germanium source such as germane (GeH₄), digermane, higher order germanes, and GeCl₄. Germanium precursor 22 can be a combination of the foregoing, and can be diluted in a carrier gas such as hydrogen, nitrogen, or helium.

During the step of forming germanium layer 20, the mole ratio of phosphine to germanium can be between 1:100 and 1:10. In certain embodiments the P:Ge ratio can be between 1:25 and 1:15, and can be about 1:22 or 1:20. At a process pressure between 10 and 30 torr, the phosphine partial pressure can be between 1*10e−5 and 1*10e−2 torr, or more commonly between 1*10e−4 and 5*10e−3 torr, and in certain embodiments can be in the range of about 6.0*10e−4 to about 1.5*10e−3 torr.

Depending on design objectives, it can be useful to form a cap 30 over germanium layer 20. Cap 30 can be used, for example, to protect the germanium or to form a silicide contact to the germanium layer. Cap 30 can be epitaxial silicon or a SiGe layer having any Ge concentration.

### EXAMPLE 1

A substrate having a SiGe (40% Ge) layer on buried oxide (a SGOI substrate) was preconditioned in hydrogen at 780 C and 500 torr. A SiGe buffer layer (40% Ge) was grown in the presence of 20 standard cubic centimeter per minute (sccm) PH₃ at partial pressure (pp) of about 2.4×10e−3 torr PH₃. A germanium layer was then formed at 320 C by exposing the substrate to germanium precursor along with 20 sccm PH₃ (pp=1.2×10e−3 torr PH₃). The germanium layer reached a thickness of about 23 nm thick in 800 seconds. The same conditions as in example 1 were used to form a thin germanium layer at a thickness in the range of 0.5 nm to 7 nm which exhibited strain greater than 1.3% where % strain is the fraction change of the in plane lattice parameter: e.g., [−(Aip−AGe)/AGe]*100, where ‘Aip’ represents ‘in-plane’ lattice spacing in angstroms and ‘AGe’ represents the lattice spacing in angstroms of pure germanium crystal (ie Ge lattice constant). In certain embodiments the germanium layer having thickness in the range of about 1 nm to 3 nm exhibited strain greater than 1.5%, even as high as about 2.8%.

### EXAMPLE 2

The substrate for this example includes a top surface of SiₓGe₁₋ₓ, where x is in the range of 0.4 to 0.7. This substrate can be formed by exposing a semiconductor substrate (such as, for example, a bulk silicon wafer, or SOI or ETSOI wafer) to SiGe precursors, in this case silane and germane, at 400-500 C for several minutes to form a SiGe region or buffer layer to a thickness of 2 nm-10 nm. Then at a process temperature between 320 C and 370 C (target 350 C), exposing the substrate (with SiGe surface) to a gas flow of 175 sccm of 10% germane (GeH₄) in hydrogen along with about 8 sccm of 10% PH₃ in hydrogen. At chamber process pressure of 30 torr and carrier gas flow of 35 slm (std liter per minute) hydrogen, PH₃ partial pressure was 6.4×10e−4 torr and the mole ratio of P to Ge was about 1:22. A smooth Ge layer formed to a thickness of about 100 nm (1000 angstrom) over the substrate on the SiGe surface in a period of about 60 minutes.

### EXAMPLE 3

A substrate having a silicon top surface such as, for example, a bulk silicon wafer, or SOI or ETSOI wafer was preconditioned in hydrogen at 780 C. Then at a process temperature between 320 C and 370 C (target 350 C), the substrate was exposed to a gas flow of 100 sccm of 20% germane (GeH₄) in hydrogen along with about 20 sccm of 5% PH₃ in hydrogen. At chamber process pressure 10 torr and carrier gas flow of 8 slm hydrogen, PH₃ partial pressure was 1.23×10e−3 torr and the mole ratio of P to Ge was about 1:20. A smooth germanium layer formed to a thickness between 1.0 to 4.5 nm in about 800 seconds. The smooth Ge layer exhibited very high strain, indicating that in spite of the substantially different lattice spacing of germanium vs the underlying SiGe layer, this Ge layer substantially maintained the crystal structure of the underlying substrate.

Consistent with example 3, this invention enables growing a smooth germanium layer directly on a silicon surface without a SiGe buffer or interlayer. This has the advantages of avoiding extra steps to form an interlayer and keeping the stack as thin as possible.

Another advantage of this process is that the resultant germanium layer can exhibit high strain. Epitaxial germanium on silicon is highly strained due to the about 4% mismatch of germanium and silicon lattices. Without wishing to be bound by theory, the phosphorous doping may act to suppress dislocations such that a resulting germanium film having thickness of up to 5 nm or more commonly in the range of 1 nm to 3 nm retains the lateral dimensions of the underlying silicon crystal. High strain can be indicative of fewer defects and better film quality (i.e. better smoothness). The highly strained film can be leveraged for improved carrier mobility such as as the channel of a field effect transistor (FET), or separately to impart significant strain onto adjacent structures such as by forming a high strained Ge layer in the source drain regions to strain the adjacent channel region.

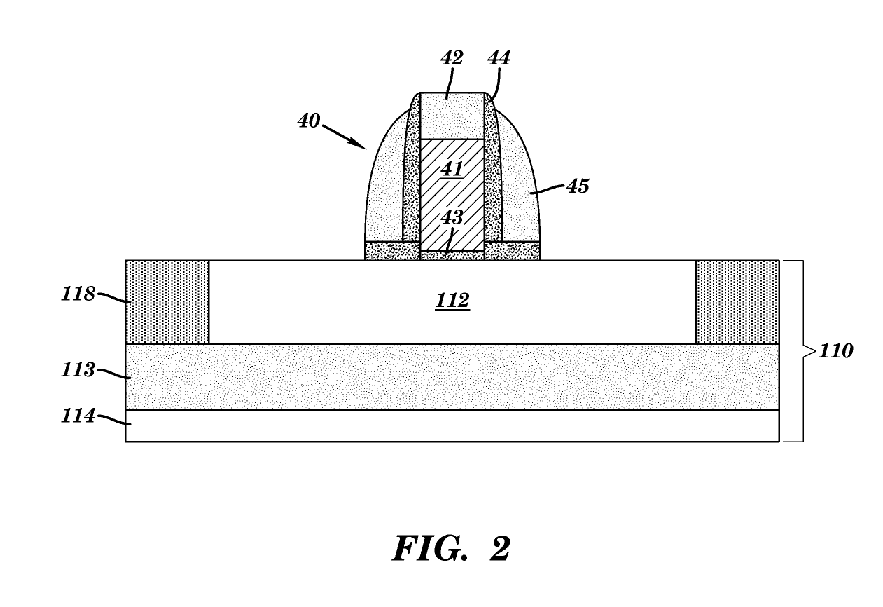

Referring now to FIG. 2, a standard CMOS structure is illustrated. Semiconductor substrate 110 includes a semiconductor region 112. Region 112 can optionally overlie other layers such as buried oxide (BOX) layer 113 on bulk material 114. An insulator region such as shallow trench isolation (STI) regions 118 can isolate a device 40 from other devices (not shown) that may be formed on substrate 110. Device 40 can be a field effect transistor (FET). As is known, device 40 can include a gate stack having a gate conductor 41, a cap layer 42, a gate dielectric 43, and various spacers 44, 45. FIG. 2 illustrates a planar FET, but this invention is equally applicable to a FINFET.

Gate conductor 41 can be formed of polysilicon, but may also include elemental metals, metal alloys, metal silicides, and/or other conductive materials.

Gate dielectric 43 is a dielectric material which can comprise one or combinations of silicon oxide (SiO₂), silicon nitride, silicon oxynitride, boron nitride, and high-k dielectrics such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

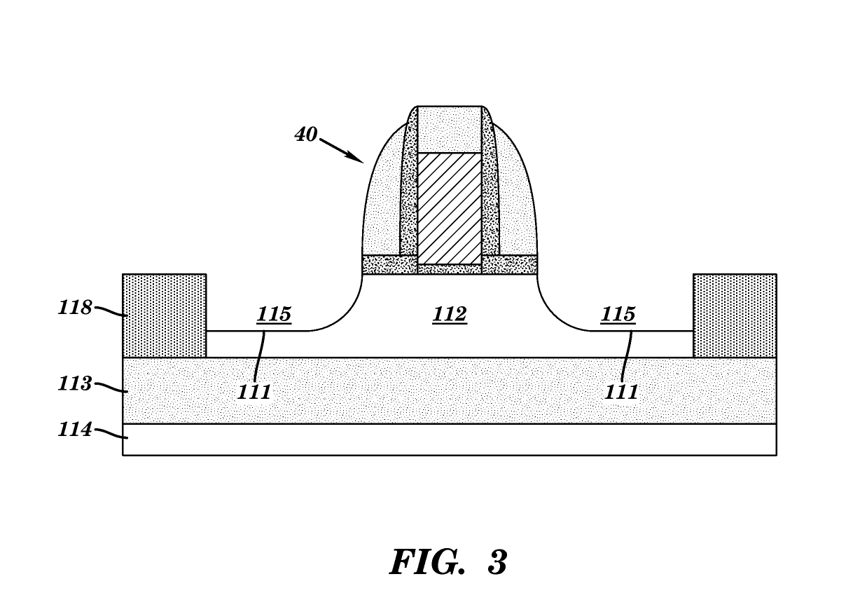

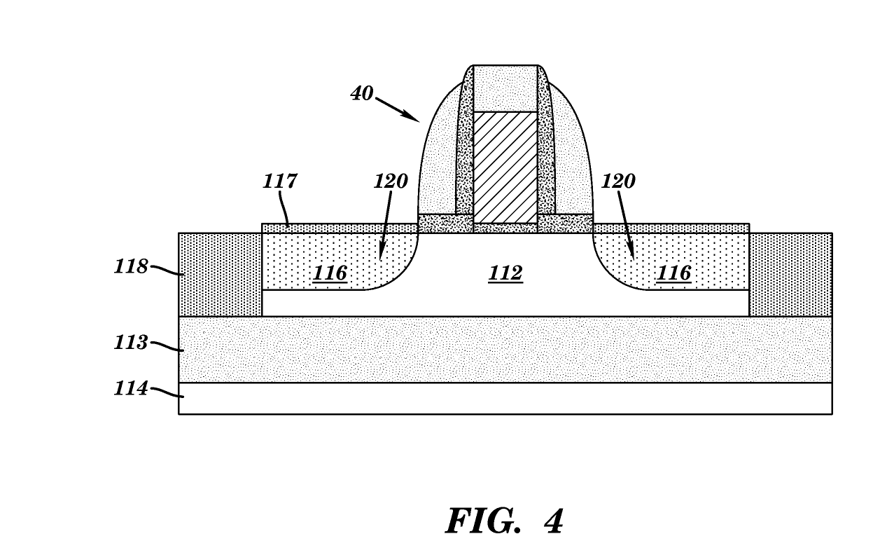

As noted, the thin strained germanium layer of the present invention could form the channel a region of a FET. A strained germanium film could be grown in a shallow recess of substrate 112, after which the gate stack could be formed. Another application for strained germanium is to impart strain on adjacent structures, such as within the source/drain of a FET to impart strain on a conventional channel. Now with reference to FIGS. 3 and 4, after applying an appropriate mask (not shown), source/drain regions 120 of the structure may undergo a reactive ion etching (RIE) process, to form recesses 115. Known methods can be used to obtain a depth and side profile of etch regions 115 according to design purposes and to retain a crystalline surface 111 at the bottom of regions 115. For example, regions 115 can be formed by a directional dry etch which can form recess 115 with substantially straight sidewalls or by a wet (or other isotropic) etch process to extend under (undercut) the gate stack.

0032 Epitaxial germanium 116 can be grown to refill regions 115 by exposing the structure to germanium precursor in the presence of a proper amount of phosphine which can be phosphine partial pressure between 1*10e−5 and 1*10e−2 torr, or more commonly between 1*10e−4 and 5*10e−3 torr, and in certain embodiments in the range of about 6.0*10e−4 to about 1.5*10e−3 torr. Germanium layer 116 having high strain can form up to about 5 nm thick, or more commonly in the range of 1 nm to 3 nm thick. Optionally, a thin Si or SiGe cap 117 can be formed over germanium layer 116 by techniques known to those skilled in the art. Such cap 117 can be used pursuant to further processing to form contacts to source/drain regions 120.

It will be apparent to those skilled in the art having regard to this disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A structure comprising:
a germanium layer disposed on a silicon layer,
said germanium layer having strain greater than 1.5%.

2. The structure of claim 1 wherein said germanium layer is disposed directly on a doped semiconductor material.

3. The structure according to claim 1 further comprising:
a silicon or SiGe cap formed over said germanium layer.

4. The structure of claim 1 wherein said germanium layer is formed directly on said silicon layer and the material of said silicon layer has chemical formula SiₓGe₁₋ₓ.

5. The structure of claim 4 wherein x=1.

6. The structure of claim 4 wherein x is in the range of 0.4 to 0.7 and said silicon layer is disposed on a substrate selected from the group consisting of bulk silicon, SOI, and ETSOI.

7. The structure of claim 4 further comprising at least one semiconductor device.

8. The structure of claim 4 wherein said material is n-doped or undoped.

9. The structure of claim 1 wherein said germanium layer constitutes the channel of a field effect transistor.

10. The structure of claim 1 wherein said germanium layer has a thickness in the range of 1 nm to 5 nm.

11. A semiconductor article comprising:
a semiconductor substrate; and
a germanium layer disposed on said semiconductor substrate, wherein said germanium includes strain greater than 1.5%.

12. The article of claim 11 comprising a field effect transistor, wherein said germanium layer is formed in a source/drain region of said field effect transistor.

13. The article of claim 12 wherein said germanium layer includes strain in the range of 1.5 to 2.8%.

14. The article of claim 11 wherein said germanium layer is formed directly on a SiGe surface.
